(19) United States
(12) Patent Application Publication
(10) Pub. No.: US 2018/0331325 A1
(43) Pub. Date: Nov. 15, 2018

(54) OLED DISPLAY PANEL, MANUFACTURING METHOD THEREOF, AND DISPLAY DEVICE

(71) Applicant: BOE Technology Group Co., Ltd., Beijing (CN)

(72) Inventor: Wei Zhang, Beijing (CN)

(73) Assignee: BOE TECHNOLOGY GROUP CO., LTD.

(21) Appl. No.: 15/839,972

(22) Filed: Dec. 13, 2017

(30) Foreign Application Priority Data
May 15, 2017 (CN) 201710338803.1

(51) Int. Cl. H01L 51/52; H01L 51/56; H01L 27/32

(52) U.S. Cl. CPC H01L 51/5271; H01L 51/5218; H01L 51/5234; H01L 2251/558; H01L 51/56; H01L 27/3246; H01L 51/5209

(57) ABSTRACT

An OLED display panel, a manufacturing method thereof and a display device is provided. The OLED display panel includes a basal substrate as well as a first pixel definition layer and a plurality of OLEDs arranged on the basal substrate. The first pixel definition layer is provided with a plurality of openings and each opening is correspondingly provided with an OLED. Each OLED includes a first electrode, a light emitting layer and a second electrode. Each first electrode is arranged on the bottom and the sidewall of the corresponding opening. The light emitting layer and the second electrode are sequentially arranged on the first electrode. The first electrode is configured to reflect the light emitted by the OLED towards the side of the OLED that is away from the basal substrate. Thus, the brightness and the light extracting efficiency of the display panel is improved.

### CROSS-REFERENCE TO RELATED APPLICATION

This application claims priority to Chinese Patent Application No.: 201710338803.1, filed with the State Intellectual Property Office on May 15, 2017 and tilted “OLED Display Panel, Manufacturing Method thereof and Display Device”, which is incorporated herein by reference in its entirety.

### TECHNICAL FIELD

The present disclosure relates to the field of display devices, and more particularly to an OLED display panel, a manufacturing method thereof and a display device.

### BACKGROUND

At present, conventional display devices comprise passive light emitting display devices, such as liquid crystal display devices, and active light emitting display devices, such as Organic Light Emitting Diode (OLED) display devices. Compared with the passive light emitting display devices, the active light emitting display devices have the advantages of smaller thickness, lower power consumption, higher response speed and the like since no backlight panel is needed, and thus have greater market competitiveness.

An OLED display device comprises an OLED display panel comprising a plurality of OLEDs. Each OLED generally comprises an anode, an organic light emitting layer and a cathode. In the OLED display panel, the anode is generally manufactured on a basal substrate first, and then an insulating pixel definition layer is arranged on the surface of the basal substrate. A plurality of openings arranged in an array are formed in the pixel definition layer, and a portion of the anode is exposed through the corresponding opening. The organic light emitting layer is manufactured on the exposed portion of the anode and disposed in the corresponding opening, and the cathode is arranged on the organic light emitting layer.

### SUMMARY

The present disclosure provides an OLED display panel, a manufacturing method thereof and a display device. The technical solutions are as follows.

In a first aspect, there is provided an OLED display panel in the present disclosure. The OLED display panel includes a basal substrate and a first pixel definition layer and a plurality of OLEDs disposed on the basal substrate. The first pixel definition layer is provided with a plurality of openings arranged in an array. The plurality of OLEDs correspond to the plurality of openings one by one. Each OLED includes a first electrode, a light emitting layer and a second electrode. Each first electrode is arranged on the bottom and the sidewall of the corresponding opening. The light emitting layer and the second electrode are sequentially arranged on the first electrode. The first electrode is configured to reflect the light emitted by the OLED.

In some embodiments, the area of the cross section of the opening is positively correlated with the distance between the cross section and the basal substrate, and the cross section of the opening refers to the cross section of the opening in the direction parallel to the basal substrate.

In some embodiments, the first electrode includes a first reflective part, a second reflective part and a third reflective part which are sequentially connected. The first reflective part is arranged on the bottom of the opening, and both the second reflective part and the third reflective part are arranged on the sidewall of the opening. The second reflective part is arranged around the first reflective part, the third reflective part is arranged around the second reflective part, and both the included angle between the second reflective part and the first reflective part and the included angle between the third reflective part and the second reflective part are obtuse angles.

In some embodiments, the vertical distance from the joint between the second reflective part and the third reflective part to the basal substrate is greater than the vertical distance from the light emitting layer to the basal substrate.

In some embodiments, the included angle between the third reflective part and the second reflective part is 120°-140°, and the included angle between the second reflective part and the first reflective part is 160°-170°.

In some embodiments, the sidewall of the opening is a concave spherical cap surface.

In some embodiments, the light emitting layer of the OLED is arranged at a focal point of the spherical cap surface.

In some embodiments, the OLED display panel further includes a second pixel definition layer covering the first pixel definition layer and regions of the first electrodes outside the light emitting layers.

In some embodiments, the second electrodes of the plurality of OLEDs are of an integral structure which is a surface electrode.

In some embodiments, the first electrode further covers the surface of the first pixel definition layer around the opening.

In some embodiments, the thickness of the first electrode is 0.4 μm-0.6 μm.

In some embodiments, the thickness of the second electrode is 80 Å-100 Å.

In some embodiments, the first electrode is an anode and the second electrode is a cathode.

In some embodiments, the first electrode is formed by sequentially laminating an ITO layer, an Ag layer and another ITO layer.

In some embodiments, the second electrode is formed by sequentially laminating an Mg layer and an Ag layer.

In another aspect, there is provided a method for manufacturing an OLED display panel in the present disclosure. The method includes: forming a first pixel definition layer on a basal substrate, where the first pixel definition layer is provided with a plurality of openings arranged in an array; forming a first electrode of an OLED in each opening of the first pixel definition layer; forming a light emitting layer on the first electrode; and forming a second electrode on the light emitting layer, where each first electrode at least covers the bottom and the sidewall of the corresponding opening, and is configured to reflect the light emitted by the OLED.

In some embodiments, before the light emitting layer is formed on the first electrode, the method further includes: forming a second pixel definition layer on the first electrodes and the first pixel definition layer.

In some embodiments, forming the first pixel definition layer on the basal substrate includes: forming a first pixel definition layer thin film on the basal substrate; and forming the plurality of openings arranged in an array in the first pixel definition layer thin film. The area of the cross section of the opening is positively correlated with the distance between the cross section and the basal substrate, and the cross section of the opening refers to the cross section of the opening in the direction parallel to the basal substrate.

In yet another aspect, there is provided an OLED display device in the present disclosure. The OLED display device includes any of the OLED display panels described above.

### BRIEF DESCRIPTION OF THE DRAWINGS

To describe the technical solutions in the embodiments of the present disclosure more clearly, the following briefly introduces the accompanying drawings required for describing the embodiments. Apparently, the accompanying drawings in the following description show merely some embodiments of the present disclosure, and a person of ordinary skill in the art may still derive other drawings from these accompanying drawings without creative efforts.

FIG. 1 is a structural schematic view of an OLED display panel provided in the embodiments of the present disclosure;

FIG. 2 is a cross section view of the dotted line box in FIG. 1;

FIG. 3 is a structural schematic view of another OLED display panel provided in the embodiments of the present disclosure;

FIG. 4 is a structural schematic view of yet another OLED display panel provided in the embodiments of the present disclosure;

FIG. 5 is a structural schematic view of yet another OLED display panel provided in the embodiments of the present disclosure;

FIG. 6 is a flow chart of a method for manufacturing an OLED display panel provided in the embodiments of the present disclosure;

FIG. 7 is a flow chart of another method for manufacturing an OLED display panel provided in the embodiments of the present disclosure;

FIG. 8 to FIG. 12 are schematic views of a process for manufacturing an OLED display provided in the embodiments of the present disclosure;

FIG. 13 is a flow chart of another method for manufacturing an OLED display panel provided in the embodiments of the present disclosure;

FIG. 14 to FIG. 15 are schematic views of a process for manufacturing an OLED display provided in the embodiments of the present disclosure.

### DETAILED DESCRIPTION

The present disclosure will be described in further detail with reference to the enclosed drawings, to clearly present the objects, technique solutions, and advantages of the present disclosure.

In a related OLED display panel, as the organic light emitting layer of an OLED is arranged in the opening of a pixel definition layer, a part of the light emitted by the organic light emitting layer will be absorbed by the pixel definition layer, resulting in a relatively low light extracting efficiency of the OLED display panel. In the embodiments of the present disclosure, the first electrode of the OLED is arranged on the bottom and the sidewall of the opening of the pixel definition layer, and configured to reflect the light emitted by the OLED, so as to improve the light extracting efficiency of the OLED display panel.

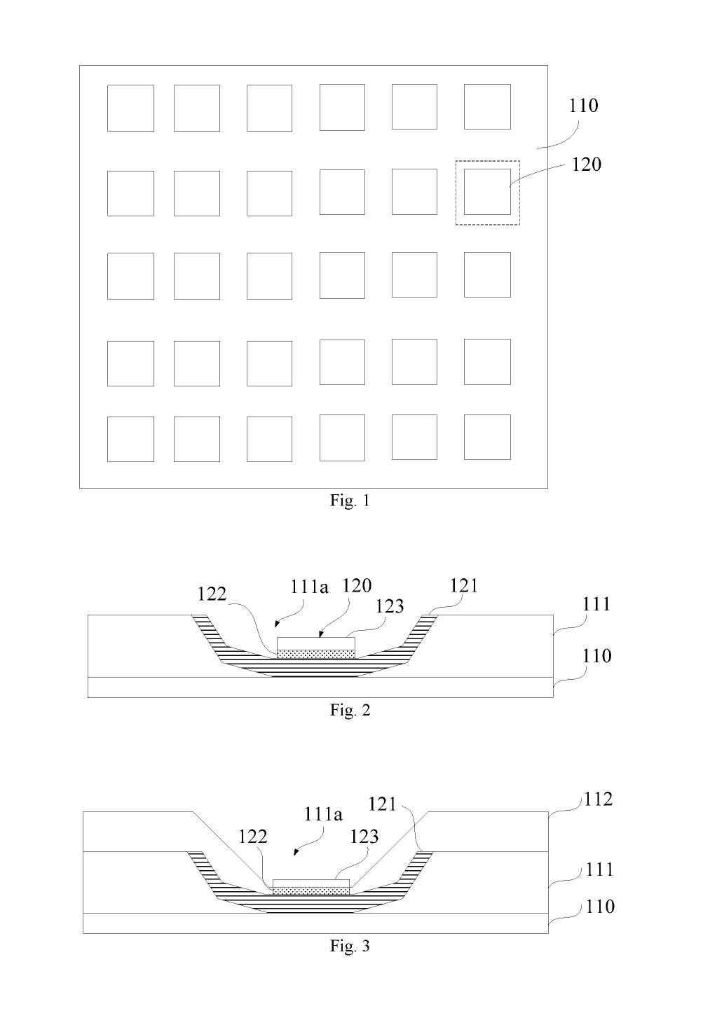

FIG. 1 is a structural schematic view of an OLED display panel provided in the embodiments of the present disclosure. As shown in FIG. 1, the OLED display panel comprises a basal substrate 110 and a plurality of OLEDs 120 arranged on the basal substrate 110 in an array.

FIG. 2 is a cross section view of the dotted line box in FIG. 1. As shown in FIG. 2, a first pixel definition layer 111 is further arranged on the basal substrate 110, and is provided with a plurality of openings 111a arranged in an array. Each opening 111a is correspondingly provided with one OLED 120. Each OLED 120 comprises a first electrode 121, a light emitting layer 122 and a second electrode 123. Each first electrode 121 is arranged on the bottom and the sidewall of the corresponding opening 111a. The light emitting layer 122 and the second electrode 123 are sequentially arranged on the first electrode 121. The first electrode 121 is configured to reflect the light emitted by the OLED 120.

In the embodiments of the present disclosure, the first electrode of the OLED covers the sidewall of the opening to form a reflective surface for reflecting the light emitted by the OLED towards a side away from the basal substrate, so as to prevent the light from entering the first pixel defined layer, thereby improving the brightness and the light extracting efficiency of the display panel. By using the first electrode for reflection, there is no need to arrange a special reflective layer, so that the process is simplified and the production efficiency is improved.

It should be noted that a thin film transistor array may also be arranged on the basal substrate 110 provided in the embodiments of the present disclosure. The plurality of OLEDs 120 and the first pixel definition layer 111 are arranged on the thin film transistor array and the first electrode 121 of each OLED 120 is electrically connected with a thin film transistor. Of course, the plurality of OLEDs 120 and the first pixel definition layer 111 may also be directly arranged on the basal substrate 110. In this case, the thin film transistor array may be arranged on the first pixel definition layer 111.

Here, one of the first electrode 121 and the second electrode 123 is an anode and the other is a cathode. Illustratively, the first electrode 121 is the anode, and the second electrode 123 is the cathode. The anode may be made of ITO/Ag/ITO (namely, an ITO layer, an Ag layer and another ITO layer being sequentially laminated). The cathode may be made of Mg/Ag (namely, an Mg layer and an Ag layer being sequentially laminated). ITO/Ag/ITO has good conductivity and reflectivity, and may improve the reflectivity to light while ensuring the electrical connection. Meanwhile, ITO/Ag/ITO has high work function that is conducive to hole transportation. Mg/Ag may improve the light transmittance and reduce the absorption of light while ensuring the electrical connection. Meanwhile, Mg/Ag has low work function that is conducive to electron transportation. Of course, the first electrode 121 and the second electrode 123 may also be made of other conductive materials.

In some embodiments, the thickness of the first electrode 221 may be 0.4 μm-0.6 μm. If the first electrode 221 is too thin, it will be in a transparent state, so that a part of the light will be transmitted through the first electrode 221. If the electrode 221 is too thick, it will cause the material waste and increase the production cost.

In some embodiments, the thickness of the second electrode 223 may be 80 Å-100 Å. If the second electrode 223 is too thin, the resistance of the second electrode 223 will be increased. If the second electrode 223 is too thick, the transparency of the second electrode 223 will be reduced, resulting in excessive light absorbed by the second electrode 223.

Here, the light emitting layer 122 may be a single-layer structure, such as an organic light emitting layer. Alternatively, the light emitting layer 122 may also be a multi-layer structure comprising, for example, a hole injection layer, a hole transport layer, an organic light emitting layer, an electron transport layer and an electron injection layer which are arranged in a laminated manner.

As shown in FIG. 1, the area of the cross section of the opening 111a is positively correlated with the distance between the cross section and the basal substrate 110. The cross section of the opening 111a refers to the cross section of the opening 111a in the direction parallel to the basal substrate 110 and the positive correlation means that the longer the distance from the cross section to the basal substrate 110 is, the larger the area of the cross section is, but the two are not necessarily directly proportional to each other. In this way, the first electrode 221 covering the bottom and the sidewall of the opening 111a may converge the reflected light in a relatively small area such that the reflected light is more concentrated, thereby facilitating the improvement of the brightness and the light extracting efficiency of the display panel.

Further, the light emitting layer 122 may be disposed in a region that is opposite to the bottom of the opening 111a, on the first electrode 121.

FIG. 3 is a structural schematic view of another OLED display panel provided in the embodiments of the present disclosure. In some embodiments, the OLED display panel shown in FIG. 3 further comprises a second pixel definition layer 112 which covers the first pixel definition layer 111 and a region of the first electrode 121 outside the light emitting layer 122. By arranging the second pixel definition layer 112 on the first electrode 121, the first electrode 121 is protected, and meanwhile the short circuit between the first electrode 121 and the second electrode 123 may be avoided.

The surface shapes of the first pixel definition layer 111 and the second pixel definition layer 112 may be different. When the OLED display panel is manufactured, the shapes of the openings 111a in the first pixel definition layer 111 may be changed to change the shapes of the formed first electrodes 121, so that the first electrodes 121 may better reflect the light.

The shape of the portion, disposed in the opening 111a, of the second pixel definition layer 112 is configured to define a pixel area. In order to avoid defects such as breakage of the electrodes manufactured subsequently, the surface of the portion, disposed in the opening 111a, of the second pixel definition layer 112 should be as smooth as possible. For example, it may be an inclined surface or a curved surface.

During the implementation, both the first pixel definition layer 111 and the second pixel definition layer 112 may be made of polyimide. Polyimide is a transparent material with high insulativity, which may effectively isolate the first electrode 121 from the second electrode 123, and reduce the absorption of the light.

FIG. 4 is a structural schematic view of another OLED display panel provided in the embodiments of the present disclosure. In some embodiments, in the OLED display panel shown in FIG. 4, the second electrodes 223 of the plurality of OLEDs are of an integral structure which is a surface electrode. By arranging the second electrodes 223 as a whole, the connection manner with a common cathode or common anode may be realized to meet different design requirements.

Further, the first electrode 221 may further cover the surface of the first pixel definition layer 111 around the opening 111a. After being reflected by the first electrode 221 to the place around the opening 111a, the light may be reflected at the joint between the second pixel definition layer 112 and the second electrode 223 or at the surface of the second electrode 223 that is away from the second pixel definition layer 112, towards the basal substrate 110. By further covering the surface of the first pixel definition layer 111 around the opening 111a with the first electrode 221, the reflected light may be reflected towards the side of the OLED away from the basal substrate 110, so that the brightness and the light extracting efficiency of the display panel are further improved.

Gaps a may be reserved between the adjacent first electrodes 221, so that the plurality of first electrodes 221 are independent from each other. The second pixel definition layer 221 is filled in the gaps a, so that the first electrodes 221 are insulated from each other.

In the embodiments of the present disclosure, the first electrode 221 may include a first reflective part 221a, a second reflective part 221b and a third reflective part 221c that are sequentially connected. The first reflective part 221a is disposed on the bottom of the opening 111a, and the second reflective part 221b and the third reflective part 221c are both disposed on the sidewall of the opening 111a. The second reflective part 221b is around the first reflective part 221a and the third reflective part 221c is around the second reflective part 221b. Both the included angle between the second reflective part 221b and the first reflective part 221a and the included angle between the third ref1 reflective section part 221c and the second reflective part 221b are obtuse angels. The first electrode 221a is arranged to be a multi-segment structure including the first reflective part 221a, the second reflective part 221b and the third reflective part 221c. In this way, the direction of the reflected light may be adjusted by changing the included angle between the first reflective part 221a and the second reflective part 221b and the included angle between the second reflective part 221b and the third reflective part 221c, such that the reflected light is more concentrated.

Further, the vertical distance h1 from the joint between the second reflective part 221b and the third reflective part 221c to the basal substrate 110 may be greater than the vertical distance h2 from the light emitting layer 122 to the basal substrate 110, so that a part of the light emitted by the light emitting layer 122 may be reflected to the third reflective part 221c through the second reflective part 221b, and be reflected towards the side away from the basal substrate 110 through the third reflective part 221c. Therefore, through twice reflection, light emitted by the light emitting layer 122 and forming a relatively small angle with the basal substrate 110 may also be reflected towards the side away from the basal substrate 110.

In some embodiments, the included angle between the third reflective part 221c and the second reflective part 221b may be 120°-140°. The included angle between the second reflective part 221b and the first reflective part 221a may be 160°-170°. By setting the included angle between the third reflective part 221c and the second reflective part 221b and the included angle between the second reflective part 221b and the first reflective part 221a in the above ranges, more light may be reflected in the direction perpendicular to the basal substrate 110.

It should be noted that the first electrode may also be of a multi-segment structure with more than three segments. Further, the first electrode 221 may comprise the first reflective part 221a, the second reflective part 221b, the third reflective part 221c and until an N^{th} reflective part which are sequentially connected with one another, wherein N≥4. The first reflective part 221a is arranged at the bottom of the opening 111a. The second reflective part 221b and until the N^{th} reflective part are all arranged on the sidewall of the opening 111a. An (i+1)^{th} reflective part is arranged around an i^{th} reflective part, wherein 1≤i≤N−1. The included angle between every two adjacent reflective parts is an obtuse angel. By arranging the first electrode 221 as the multi-segment structure, the light emitted by the light emitting layer 122 and forming a relatively small angle with the basal substrate 110 may be reflected towards the side of the OLED that is away from the basal substrate 110 through multiple reflection of the first electrode 221, so that the light extracting efficiency is further improved.

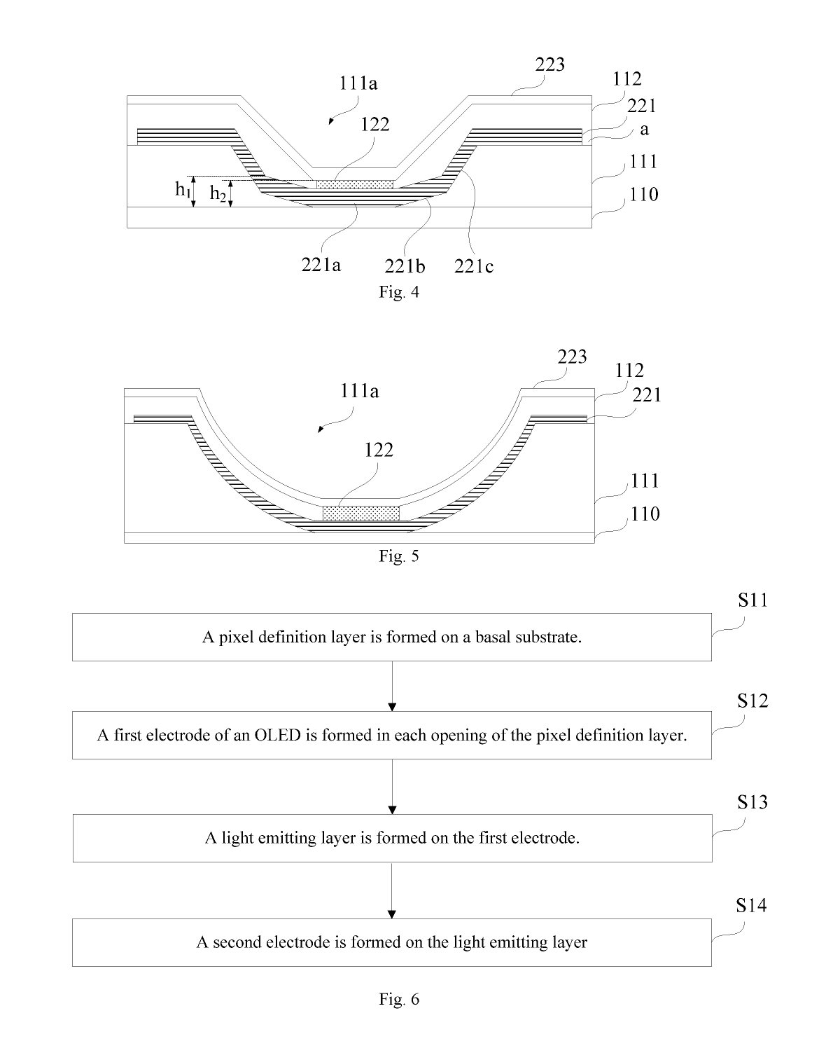

FIG. 5 is a structural schematic diagram of another OLED display panel provided in the embodiments of the present disclosure. In some embodiments, in the OLED display panel shown in FIG. 5, the sidewall of the opening 111a may be a concave spherical cap surface. Since the sidewall of the opening 111a is a spherical cap surface, the portion of the first electrode 221 that covers the sidewall of the opening 111a is also a spherical cap surface. When the first electrode 221 with the spherical cap surface reflects light, the reflected light is more concentrated, which facilitates the improvement of the brightness and the light extracting efficiency of the display panel.

Further, the light emitting layer 122 of the OLED is disposed at the focal point of the spherical cap surface. By disposing the light emitting layer 122 of the OLED at the focal point of the spherical cap surface, the light emitted by the light emitting layer 122 becomes collimated light beams after being reflected by the first electrode 221, which may further improve the brightness and the light extracting efficiency of the display panel.

During the implementation, the geometric center of the light emitting layer 122 may coincide with the focal point of the spherical cap surface, so that the light emitted by the light emitting layer 122 may be approximately emitted from the focal point. After being reflected by the first electrode 221, the light becomes collimated light beams such that the light is more concentrated, which may improve the brightness and the light extracting efficiency of the display panel.

FIG. 6 is a flow chart of a method for manufacturing an OLED display panel provided in the embodiments of the present disclosure. The method is used to manufacture the OLED display panel shown in FIG. 2. As shown in FIG. 6, the method includes: forming a pixel definition layer on a basal substrate. The pixel definition layer is provided with a plurality of openings arranged in an array. A first electrode of an OLED is formed in each opening of the pixel definition layer; forming a light emitting layer on the first electrode; and forming a second electrode on the light emitting layer.

Here, each first electrode at least covers the bottom and the sidewall of the corresponding opening and is configured to reflect the light emitted by the OLED.

In the embodiments of the present disclosure, the first electrode of the OLED covers the sidewall of the opening to form a first reflective surface to reflect the light emitted by the OLED towards the side of the OLED that is away from the basal substrate, thereby preventing the light from entering the first pixel definition layer and improving the brightness and the light extracting efficiency of the display panel. By adopting the first electrode for reflection, no special reflective layer needs to be arranged. Thus, the process is simplified and the production efficiency is improved.

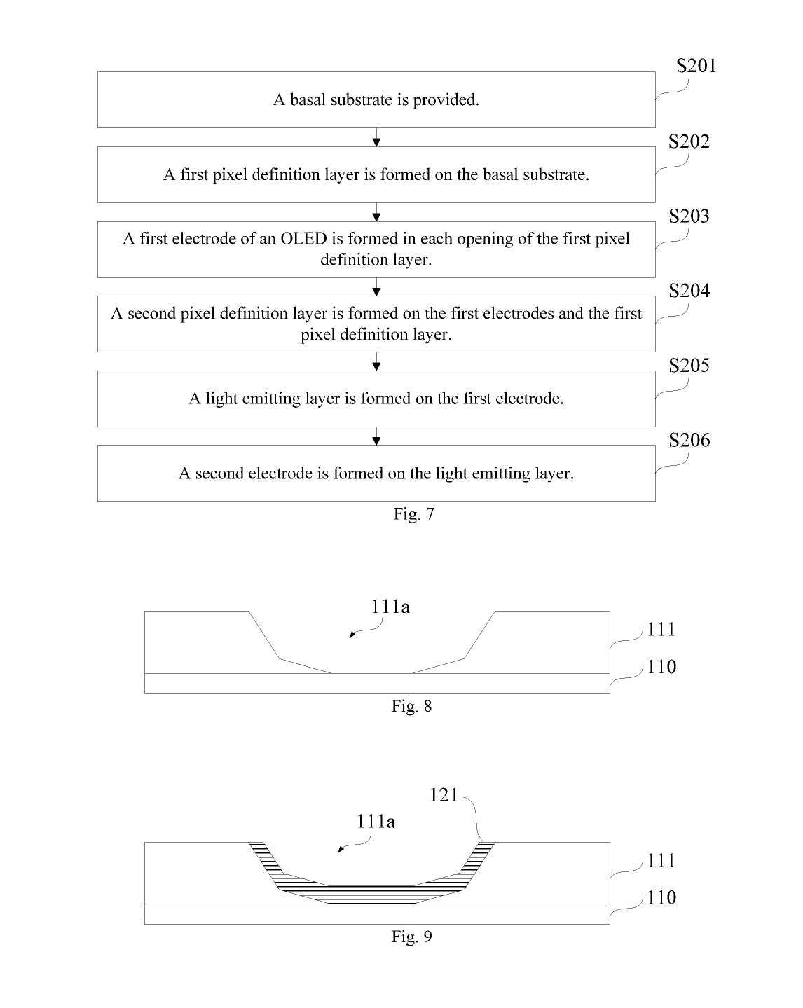

FIG. 7 is a flow chart of another method for manufacturing an OLED display panel provided in the embodiments of the present disclosure. The method is used to manufacture the OLED display panel shown in FIG. 3. The method will be described below with reference to FIG. 8 to FIG. 12. As shown in FIG. 7, the method includes:
S201: a basal substrate is provided.

The basal substrate may be a transparent substrate, such as a glass substrate, a silicon substrate, a plastic substrate, or the like. In step S201, the basal substrate may be cleaned.
S202: a first pixel definition layer is formed on the basal substrate.

As shown in FIG. 8, the first pixel definition layer 111 is provided with a plurality of openings 111a arranged in an array.

Step 202 may include: forming a layer of first pixel definition layer thin film on the basal substrate 110; and forming the plurality of opening 111a arranged in an array in the first pixel definition layer thin film.

Here, the area of the cross section of the opening 111a is positively correlated with the distance between the cross section and the basal substrate 110. The cross section of the opening 111a refers to the cross section of the opening 111a in the direction parallel with the basal substrate 110.

In some embodiments, the plurality of openings 111a arranged in an array may be formed on the basal substrate 110 through a patterning process.

During the implementation, the basal substrate 110 may be coated with a layer of polyimide to form the first pixel definition layer thin film. In the patterning process, a semi-transparent mask may be used for exposure, so that the plurality of openings 111a arranged in an array are formed in the first pixel definition layer 111 through a photolithography process. The basal substrate 110 is exposed through the bottoms of the openings 111a. By using different semi-transparent masks for exposure, the openings 111a with different shapes of sidewalls may be formed. Due to the different shapes of the sidewalls, the shapes of the first electrodes formed in the subsequent steps are different, so that the reflection effects on light are also different. By forming the openings 111a with a suitable shape, the first electrodes formed in the subsequent steps may better reflect light. For example, the sidewall of the opening 111a may be a concave spherical cap surface, so that the reflected light can be more concentrated, thereby facilitating the improvement of the brightness and the light extracting efficiency of the display panel.
S203: a first electrode of an OLED is formed in each opening of the first pixel definition layer.

As shown in FIG. 9, a first electrode 121 is formed in the opening 111a.

Step 203 may include: forming a first electrode material thin film on the first pixel definition layer 111; and forming a plurality of first electrodes 121 through a patterning process.

During the implementation, the first electrode material thin film may be formed on the first pixel definition layer 111 through magnetron sputtering or evaporation. The first electrode material thin film covers the surface of the first pixel definition layer 111 and the basal substrate 110 exposed by the bottoms of the openings 111a.

In some embodiments, when the first electrode 121 serves as an anode, the first electrode material thin film may be ITO/Ag/ITO. When the first electrode 121 serves as a cathode, the first electrode material thin film may be Mg/Ag.

The first electrode material thin film is processed through the patterning process to form a pattern with a plurality of first electrodes 121 arranged in an array and separated from each other. Each of the first electrodes 121 may cover the bottom and the sidewall of the corresponding opening 111a.
S204: a second pixel definition layer is formed on the first electrodes and the first pixel definition layer.

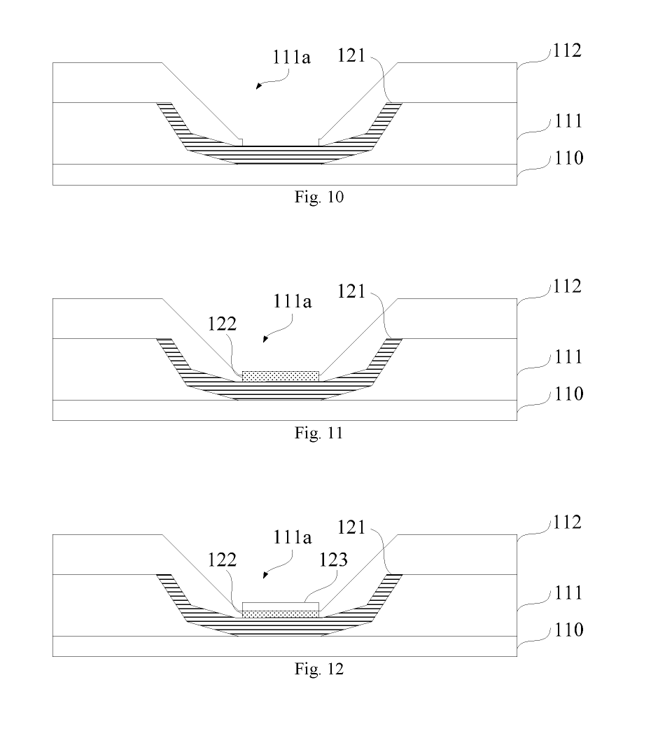

As shown in FIG. 10, the second pixel definition layer 112 is formed on the first electrodes 121 and the first pixel definition layer 111.

Step 2014 may include: forming a layer of second pixel definition layer thin film on the first electrodes 121 and the first pixel definition layer 111; and forming the second pixel definition layer 112 on the first electrodes 121 and the first pixel definition layer 111 through a patterning process.

During the implementation, the first electrodes 121 and the first pixel definition layer 111 may be coated with a layer of polyimide to form a second pixel definition layer thin film. In the patterning process, a part of the second pixel definition layer thin film is removed to form the second pixel definition layer 112. Regions of the first electrodes 121 at the bottoms of the opening s111a are exposed by the second pixel definition layer 112 to facilitate the manufacture of the subsequent structures

In some embodiments, a semi-transparent mask may be used for exposure in the patterning process, so that when the second pixel definition layer 112 is processed through the photolithography process, the surface shape of the portion of the second pixel definition layer 112 that is located in the openings 111a can meet the design requirement. For example, under the condition that the size of a defined pixel region meets the requirement, the surface of the second pixel definition layer 112 may be manufactured as smooth as possible, such as, manufactured as an inclined surface or a curved surface, so as to avoid defects such as breakage of the cathode manufactured subsequently.

Step S205: a light emitting layer is formed on the first electrode.

As shown in FIG. 11, the light emitting layer 122 is formed on the first electrode 121.

In some embodiments, the light emitting layer 122 may be formed on the first electrode 121 through a mask plate by evaporation.

During the implementation, when the light emitting layer 122 is formed, a hole injection layer, a hole transport layer, an electron transport layer and an electron injection layer may also be sequentially formed on the first electrode 121 by evaporation. The hole transport layer is laminated on the hole injection layer, the light emitting layer is laminated on the hole transport layer, the electron transport layer is laminated on the light emitting layer, and the electron injection layer is laminated on the electron transport layer.
S206: a second electrode is formed on the light emitting layer.

As shown in FIG. 12, the second electrode 123 is formed on the light emitting layer 122.

Step 206 may include: forming a layer of second electrode material thin film on the second pixel definition layer 112 and the light emitting layer 122; and forming a plurality of second electrodes 123 through a patterning process.

During the implementation, a layer of second electrode material thin film may be formed on the second pixel definition layer 112 and the light emitting layer 122 through magnetron sputtering or evaporation. The second electrode material thin film covers surface of the second pixel definition layer 112 and the surface of the light emitting layer 122.

In some embodiments, when the second electrode 123 serves as an anode, the second electrode material thin film may be ITO/Ag/ITO. When the second electrode 123 serves as a cathode, the second electrode material thin film may be Mg/Ag.

The second electrode material thin film is processed through a patterning process to form a pattern with a plurality of second electrodes arranged in an array and separated from each other. Each of the second electrodes may cover the surface of the corresponding light emitting layer.

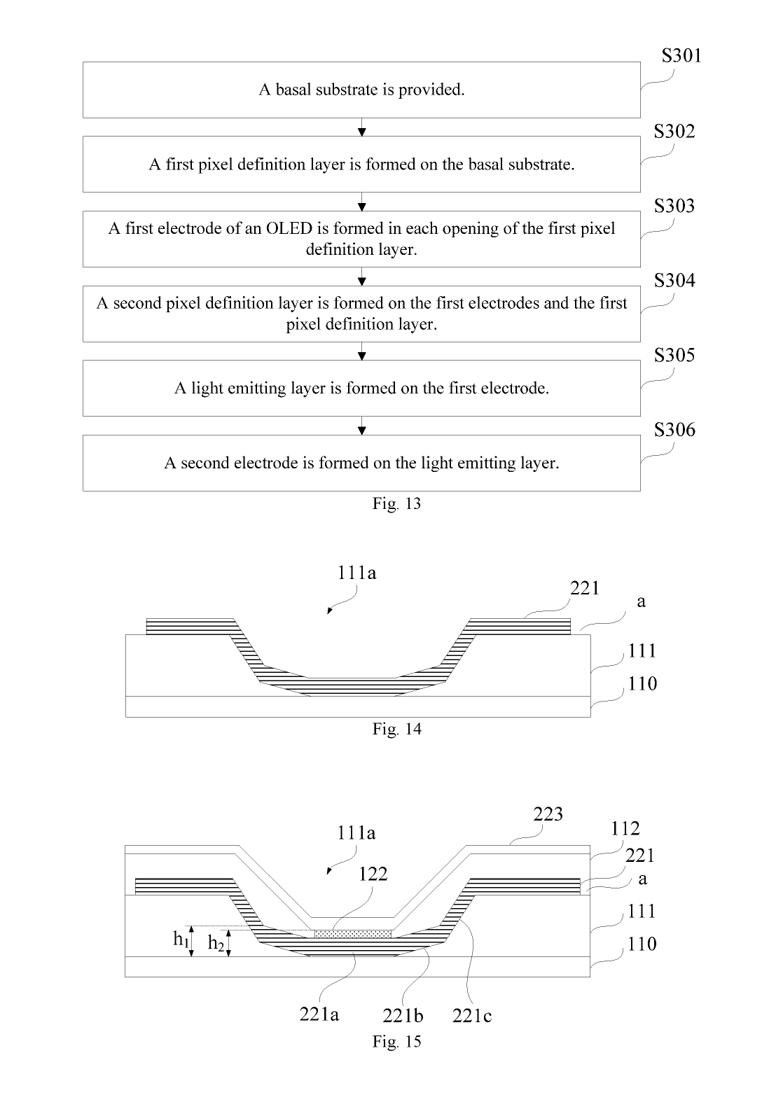

FIG. 13 is a flow chart of a method for manufacturing another OLED display panel provided in the embodiments of the present disclosure. The method is used to manufacture the OLED display panel shown in FIG. 4 or FIG. 5. The method is described below with reference to FIG. 14 to FIG. 15. The method includes:
S301: a basal substrate is provided.
S301 may be the same as S201 and will not be repeated here.
S302: a first pixel definition layer is formed on the basal substrate.
S302 may be the same as S202 and will not be repeated here.
S03: a first electrode of an OLED is formed in each opening of the first pixel definition layer.

As shown in FIG. 14, the first electrode 221 is formed in the opening 111a in the first pixel definition layer 111.

The steps S303 and S203 are basically the same, and the difference therebetween lies in that when the first electrode material thin film is processed through the patterning process, the selected masks are different, so that the first electrode 221 further covers the surface of the first pixel definition layer 111 around the opening 111a, and there is a gap between every adjacent first electrodes.
S304: a second pixel definition layer is formed on the first electrodes and the first pixel definition layer.
S304 may be the same as S204 and will not be repeated here.
S305: a light emitting layer is formed on the first electrode.
S305 may be the same as S205 and will not be repeated here.
S306: a second electrode is formed on the light emitting layer.

As shown in FIG. 15, the second electrode 223 is formed on the second pixel definition layer 112.

The steps S306 and S206 are basically the same, and the difference therebetween lies in that when the second electrode material thin film is processed through the patterning process, the selected masks are different, so that a plurality of second electrodes 223 are connected as a whole. Illustratively, the second electrodes 223 of all the OLEDs may be connected as a surface electrode, or the second electrodes 223 of a part of the OLEDs may be connected as a surface electrode to realize the connection with a common cathode or common anode. Of course, when all of the second electrodes 223 are set as a surface electrode and the second electrode material thin film is directly formed in the whole area, the step of processing the second electrode material film thin through the patterning process may also be omitted.

It should be noted that in the embodiments of the present disclosure, the arrangement on the basal substrate may comprise direct arrangement and indirect arrangement. The indirect arrangement means that there is another structure, such as a thin film transistor array or the like, between the basal substrate and the first pixel definition layer.

The embodiments of the present disclosure further provide an OLED display device, including the OLED display panel described above. The display device may be a mobile phone, a tablet computer, a TV, a display, a laptop computer, a digital photo frame, a navigator or any other product or part with display function.

In the embodiments of the present disclosure, the first electrode of the OLED covers the sidewall of the opening to form a reflective surface for reflecting the light emitted by the OLED towards the side of the OLED that is away from the basal substrate, thereby preventing the light from entering the first pixel definition layer and improving the brightness and the light extracting efficiency of the display panel. By adopting the first electrode for reflection, no special reflective layer needs to be arranged. Thus, the process is simplified and the production efficiency is improved.

The foregoing are only some embodiments of the present disclosure, and are not intended to limit the present disclosure. Within the spirit and principles of the disclosure, any modifications, equivalent substitutions, improvements, etc., are within the scope of protection of the present disclosure.

What is claimed is:

1. An OLED display panel, comprising:
a basal substrate;
a first pixel definition layer disposed on the basal substrate and provided with a plurality of openings arranged in an array; and
a plurality of OLEDs corresponding to the plurality of openings one by one, wherein each OLED comprises:
a first electrode arranged on a bottom and a sidewall of the corresponding opening and configured to reflect light emitted by the OLED; and
a light emitting layer and a second electrode which are sequentially arranged on the first electrode.

2. The OLED display panel of claim 1, wherein an area of a cross section of the opening is positively correlated with a distance between the cross section and the basal substrate, and the cross section of the opening refers to the cross section of the opening in a direction parallel to the basal substrate.

3. The OLED display panel of claim 2, wherein the first electrode comprises a first reflective part, a second reflective part and a third reflective part which are sequentially connected; the first reflective part is arranged on the bottom of the opening, both the second reflective part and the third reflective part are arranged on the sidewall of the opening, the second reflective part is arranged around the first reflective part, the third reflective part is arranged around the second reflective part, and both an included angle between the second reflective part and the first reflective part and an included angle between the third reflective part and the second reflective part are obtuse angles.

4. The OLED display panel of claim 3, wherein a vertical distance from a joint between the second reflective part and the third reflective part to the basal substrate is greater than a vertical distance from the light emitting layer to the basal substrate.

5. The OLED display panel of claim 3, wherein the included angle between the third reflective part and the second reflective part is 120°-140°, and the included angle between the second reflective part and the first reflective part is 160°-170°.

6. The OLED display panel of claim 3, wherein the sidewall of the opening is a concave spherical cap surface.

7. The OLED display panel of claim 6, wherein the light emitting layer of the OLED is arranged at a focal point of the spherical cap surface.

8. The OLED display panel of claim 1, further comprising: a second pixel definition layer covering the first pixel definition layer and regions of the first electrodes outside the light emitting layers.

9. The OLED display panel of claim 8, wherein the second electrodes of the plurality of OLEDs are of an integral structure which is a surface electrode.

10. The OLED display panel of claim 9, wherein the first electrode further covers a surface of the first pixel definition layer around the opening.

11. The OLED display panel of claim 1, wherein a thickness of the first electrode is 0.4 μm-0.6 μm.

12. The OLED display panel of claim 1, wherein a thickness of the second electrode is 80 Å-100 Å.

13. The OLED display panel of claim 1, wherein the first electrode is an anode and the second electrode is a cathode.

14. The OLED display panel of claim 13, wherein the first electrode is formed by sequentially laminating an ITO layer, an Ag layer and another ITO layer.

15. The OLED display panel of claim 13, wherein the second electrode is formed by sequentially laminating an Mg layer and an Ag layer.

16. A method for manufacturing an OLED display panel, comprising:
forming a first pixel definition layer on a basal substrate, wherein the first pixel definition layer is provided with a plurality of openings arranged in an array;
forming a first electrode of an OLED in each opening of the first pixel definition layer;
forming a light emitting layer on the first electrode; and
forming a second electrode on the light emitting layer, wherein each first electrode at least covers a bottom and a sidewall of a corresponding opening, and is configured to reflect light emitted by the OLED.

17. The method for manufacturing an OLED display panel of claim 16, wherein before the light emitting layer is formed on the first electrode, the method further comprises:
forming a second pixel definition layer on the first electrodes and the first pixel definition layer.

18. The method for manufacturing an OLED display panel of claim 16, wherein forming the first pixel definition layer on the basal substrate comprises:
forming a first pixel definition layer thin film on the basal substrate; and
forming the plurality of openings arranged in an array in the first pixel definition layer thin film, and an area of a cross section of the opening is positively correlated with a distance between the cross section and the basal substrate, wherein the cross section of the opening refers to the cross section of the opening in a direction parallel to the basal substrate.

19. An OLED display device, comprising: an OLED display panel comprising a basal substrate as well as a first pixel definition layer and a plurality of OLEDs which are arranged on the basal substrate, wherein the first pixel definition layer is provided with a plurality of openings arranged in an array, each opening is correspondingly provided with one OLED, each OLED comprises a first electrode, a light emitting layer and a second electrode, each first electrode is arranged on a bottom and a sidewall of the corresponding opening, the light emitting layer and the second electrode are sequentially arranged on the first electrode, and the first electrode is configured to reflect light emitted by the OLED.

20. The OLED display device of claim 19, wherein the OLED display panel further comprises a second pixel definition layer covering the first pixel definition layer and regions of the first electrodes outside the light emitting layers.
